(19) United States
(12) Patent Application Publication
(10) Pub. No.: US 2009/0056112 A1
(43) Pub. Date: Mar. 5, 2009

(54) ELECTROSTATIC CHUCK MEMBER, METHOD OF MANUFACTURING THE SAME, AND ELECTROSTATIC CHUCK DEVICE

(75) Inventor: Hiroyuki Kobayashi, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/201,392

(22) Filed: Aug. 29, 2008

(30) Foreign Application Priority Data
Sep. 3, 2007 (JP) 2007-228067

(51) Int. Cl. H02N 13/00; H01L 21/67; B23B 31/28

(52) U.S. Cl. 29/739; 29/592.1; 279/128; 361/234; 29/729

(57) ABSTRACT

A plurality of protruded portions is formed through embossing and is distributed and arranged regularly or irregularly on an electrostatic chuck surface, and has a circular or almost circular top surface shape and a roundness (R) of 0.01 mm or more is applied to an edge part defined by an intersection of the top surface and a side surface and a portion to which the roundness is applied occupies a quarter of a height h of the protruded portion or more.

### BACKGROUND OF THE INVENTION

The present invention relates to an electrostatic chuck member and an electrostatic chuck device, and more particularly to an electrostatic chuck member to be used for holding and fixing a substance to be processed such as a semiconductor wafer by utilizing an electrostatic chucking force in a manufacture of a semiconductor device and an electrostatic chuck device including the electrostatic chuck member. The invention also relates to a method of manufacturing the electrostatic chuck member.

In a manufacture of a semiconductor device, as is well known, a semiconductor wafer formed of silicon is subjected to various processings such as etching and sputtering with the semiconductor wafer fixed by a chuck device in a processing apparatus when the semiconductor wafer is to be processed, for example. In the chuck device, means for holding and fixing the semiconductor wafer includes means for utilizing a mechanical fixing force and means for utilizing an electrostatic chucking force. At present, the latter electrostatic chuck device is a mainstream. The electrostatic chuck device is usually constituted by an electrostatic chuck member formed of a metal or ceramic, and an electrostatic chuck surface is formed on a surface thereof and an electrode for electrostatic adsorption is incorporated in the electrostatic chuck member.

In recent years, a wiring rule of the semiconductor wafer has been subjected to ultrafining and a small emboss (protrusion) is generally provided on an electrostatic chuck surface in order to correspond thereto. Referring to the “emboss”, a name is changed depending on a manufacturer for an electrostatic chuck member, and it is possible to understand that “dimple” and “mesa” are also synonymous with the “emboss”, for example. When a large number of embosses are provided on the electrostatic chuck surface, it is possible to improve a soaking property during a wafer processing and a dechuck operation after the processing. Thus, the emboss has a function capable of greatly influencing a characteristic of the electrostatic chuck. Therefore, a size, a quantity and a height of the emboss are closely calculated. In addition, an arrangement of the emboss is devised to come in contact with the wafer in a good balance. With reference to FIG. 1, general description will be given. A conventional electrostatic chuck 100 has a substrate 101 formed of aluminum and an electrostatic chuck member 103 such as alumina ceramics is laminated on a surface of the substrate 101 through an adhesive 102, for example. The electrostatic chuck member 103 has a surface (that is, an electrostatic chuck surface) provided with a large number of embosses 104. The emboss 104 usually has a configuration of a cylindrical projection. Moreover, the respective embosses 104 usually have surfaces 104a which are subjected to a mirror processing, and have a surface roughness Ra of 0.2 μm or less. In the emboss 104, an outer peripheral end e of the surface is cut away at a sharp edge as shown. Moreover, a surface 103a in a region of the electrostatic chuck member 103 which has no emboss is subjected to blasting for forming the emboss. Therefore, the surface roughness Ra is approximately 0.2 to 1 μm.

Specific description will be given. Patent Document 1 has proposed a technique for carrying out pressurization and burning in a state in which a sheet material obtained by weaving a fiber formed by a heat-resistant inorganic material is caused to come in close contact with an insulating base material constituted by a ceramic matter and forming a dimple derived from a fiber on the insulating base material through a transfer in order to easily form a dimple having a suitable size and shape without causing a reduction in a productivity.

Moreover, Patent Document 2 has proposed a method including the steps of forming a ceramics dielectric layer acting as an electrostatic adsorbing surface on a ceramics plate and then scraping a surface of the ceramics dielectric layer partially thinly by a method such as blasting to carry out a dimple processing of forming a large number of concavo-convex portions in order to provide an electrostatic chuck which has a high durability and a long lifetime and can easily be reused.

Recently, a very small particle (a so-called fine particle) which is not a conventional problem has been regarded as questionable with a further advancement of ultrafining. As will be understood from the following description, the particle contains an abrasive grain generated by rubbing a wafer, for example. In case of an electrostatic chuck provided with an emboss, for example, a surface thereof takes a concavo-convex shape. For this reason, the particle is generated.

There has already been proposed a method of preventing the generation of a particle. For example, in Patent Document 3, the following has been recognized. As shown in FIG. 2, when a dielectric layer 153 is formed on a metal electrode 151 and an emboss 157 is further provided on a surface of the dielectric layer 153, a particle 156 is caused by shaving due to a friction of a silicon wafer 158 and the dielectric layer 153 and is deposed on the surface of the dielectric layer 153, and furthermore, is stuck to a back face of the silicon wafer 158 through an electrostatic chucking force. In order to eliminate the problems of the generation of the particle, moreover, the Patent Document 3 has proposed that a plurality of embosses is formed on an upper surface of an insulating block put on a metal block and a metal electrode and a thin dielectric layer are arranged on the embosses in order, and a metal plate is disposed in only a region having no emboss on the insulating block. In case of the method, however, a structure of an electrostatic chuck is complicated and a poor reliability and yield of the electrostatic chuck is obtained.
[Patent Document 1] JP-A-2000-277594 (Summary and Claims)
[Patent Document 2] JP-A-2003-264223 (Summary and Claims)
[Patent Document 3] JP-A-2004-253402 (Summary and Claims)

### SUMMARY OF THE INVENTION

The invention has been made in consideration of the problems of the conventional electrostatic chuck having an emboss and has an object to provide an improved electrostatic chuck member which can cope with ultrafining of a semiconductor device and can improve effects derived from the emboss, for example, a soaking property during a wafer processing and a dechuck operation after the processing and can avoid the generation of a particle without causing a structure of an electrostatic chuck and a manufacturing process from being complicated.

Moreover, it is an object of the invention to provide a method capable of easily manufacturing the improved electrostatic chuck member without damaging a reliability, a yield and a productivity.

Furthermore, it is an object of the invention to provide an improved electrostatic chuck device having no problem caused by an electrostatic chuck when it is used in a manufacture of a semiconductor device.

The above and other objects of the invention will be easily understood from the following detailed description.

The inventor first investigated the cause of the generation of the particle in the electrostatic chuck. As a result, it is supposed that a generating source includes (1) a processed substance itself, for example, a semiconductor wafer and a component itself of the electrostatic chuck such as a chuck component, (2) an atmosphere around the electrostatic chuck, and (3) rubbing of members during a processing, for example, rubbing of wafers or the wafer and the chuck component. Referring to the generating sources (1) and (2), particularly, it is possible to suppress the generation of the particle by utilizing aging or a non-operating state. For this reason, it is found that an improvement does not particularly need to be carried out in the invention. Referring to the generating source (3), however, it is impossible to suppress the generation of the particle until a coefficient of friction is zero. For this reason, the inventor studied the invention by focusing on this respect.

There is obtained the following knowledge. More specifically, when the particles are generated by a friction in the electrostatic chuck, many of them are generated between the wafer and the electrostatic chuck, and furthermore, the respective particles are moved to a back face of the wafer during the processing for the wafer so that the stuck particles adversely influence the electrostatic chuck. In other words, when the particles are laminated on the back face of the wafer and the wafer processed completely is delivered to a cassette housing portion through a handler in that state, the particles are dropped onto a surface of another wafer provided in a lower stage through a vibration or a gravity drop before, during or after accommodation so that they might cause a new defect of the wafer, for example, an undesirable change in an aspect ratio of a wiring on the wafer.

The problem that the generated particles are laminated on the back face of the wafer can be eliminated to some extent through a reduction in a dimension of an emboss provided on the surface of the electrostatic chuck or a decrease in the number of the embosses to reduce a contact area of the emboss and the wafer. The solution depends on a reduction or decrease in the embosses. Even if the number of the generated particles can be reduced, therefore, an enforcement has a limit. Actually, advantages derived from the emboss cannot be fully exhibited. Therefore, it is impossible to correspond to a next generation wafer process and apparatus. In the situation, the inventor found that the object can be achieved by smoothing the surface of the emboss provided on the electrostatic chuck, which could not be anticipated at all, and finished the invention.

According to a first aspect of the invention, there is provided an electrostatic chuck member to be used for holding a substance to be processed in a manufacture of a semiconductor device, including:

a base material, and

a plurality of protruded portions formed on an electrostatic chuck surface of the base material through embossing, wherein

the protruded portion is distributed and arranged regularly or irregularly on the electrostatic chuck surface and has a circular or almost circular top surface shape,

a roundness (R) of 0.01 mm or more is applied to an edge part defined by an intersection of the top surface and a side surface, and

a portion to which the roundness is applied occupies a quarter of a height (h) of the protruded portion or more, and

the roundness is applied by smoothing the edge part of the protruded portion through a post-processing including polishing or blasting after forming the protruded portion on the electrostatic chuck surface through the embossing, or is applied by smoothing the edge part of the protruded portion when forming the protruded portion on the electrostatic chuck surface through the embossing.

According to a second aspect of the invention, there is provided the electrostatic chuck member according to the first aspect, wherein

the top surface of the protruded portion has a diameter of 0.2 to 2 mm and a height of 0.01 to 0.03 mm.

According to a third aspect of the invention, there is provided the electrostatic chuck member according to the first or second aspect, wherein

the base material is formed of a metal or ceramic.

According to a forth aspect of the invention, there is provided the electrostatic chuck member according to any one of the first to third aspects, wherein

the base material is formed of alumina ceramic.

Moreover, according to a fifth aspect, there is provided a method of manufacturing the electrostatic chuck member according to the first aspect, including the steps of:

smoothing an edge part of the protruded portion under presence of masking unit, and

applying a roundness (R) to the edge part, wherein

the roundness is applied to the edge part of the protruded portion through a post-processing including polishing or blasting after forming the protruded portion on the electrostatic chuck surface through embossing, or applied to the edge part of the protruded portion when forming the protruded portion on the electrostatic chuck surface through the embossing.

According to a sixth aspect of the invention, there is provided the manufacturing method according to the fifth aspect, wherein

after forming the protruded portion on the electrostatic chuck surface through the embossing,

the edge part of the protruded portion is processed with a softer grinding material than the electrostatic chuck member under presence or non-presence of the masking unit for protecting at least a central part of a top surface of the protruded portion to apply the roundness.

According to a seventh aspect of the invention, there is provided the manufacturing method according to the fifth aspect, wherein

after forming the protruded portion on the electrostatic chuck surface through the embossing, the edge part of the protruded portion is processed with a grinding material constituted by finer abrasive grains than a grinding material used in the embossing under presence or non-presence of the masking unit for protecting at least a central part of a top surface of the protruded portion to apply the roundness.

According to an eighth aspect of the invention, there is provided the manufacturing method according to the fifth aspect, wherein

when forming the protruded portion on the electrostatic chuck surface through the embossing, the protruded portion is processed with a grinding material having a grain size of 250 to 44 μm in a state in which the edge part is exposed under presence of negative type masking unit corresponding to a top surface of the protruded portion to be formed to apply the roundness.

According to a ninth aspect of the invention, there is provided the manufacturing method according to any one of the fifth to eighth aspects, wherein

the embossing is carried out through sand blasting.

Furthermore, according to a tenth aspect of the invention, there is provided an electrostatic chuck device including:

the electrostatic chuck member according to any one of the first to forth aspects, and

a substrate including the electrostatic chuck member with an electrostatic chuck surface exposed from an upper surface.

According to the invention, as will be understood from the following detailed description, the edge part is broken in the protruded portion formed on the electrostatic chuck surface and is thus rounded so that the surface is smoothed. Thus, it is possible to eliminate a drawback that the semiconductor wafer is caught on the edge part. Accordingly, it is possible to suppress the generation of the particles.

As a result, according to the invention, it is possible to cope with ultrafining of a wiring rule, to control a wafer temperature in the process and to achieve a soaking property during the wafer processing, and furthermore, to improve a dechuck operation after the wafer processing in the manufacture of the semiconductor device. In addition, the structure of the electrostatic chuck according to the invention is not complicated. Therefore, it is possible to easily manufacture the semiconductor device without deteriorating a reliability, a yield and a productivity.

### BRIEF DESCRIPTION OF THE DRAWINGS

FIG. 1 is a sectional view showing a typical example of a conventional electrostatic chuck having an emboss.

FIG. 2 is a sectional view typically showing a situation of generation of a particle in the conventional electrostatic chuck having an emboss.

FIG. 3 is a sectional view showing a state in which an electrostatic chuck device having an emboss according to the invention is used to electrostatically adsorb a semiconductor wafer.

FIG. 4 is a sectional view typically showing a preferred example of an emboss portion of the electrostatic chuck member having an emboss according to the invention.

FIG. 5 is a perspective view typically showing another preferred example of the emboss portion of the electrostatic chuck member having an emboss according to the invention.

FIGS. 6A to 6D are sectional views sequentially showing a process for manufacturing a mask sheet to be used for manufacturing the electrostatic chuck member having an emboss according to the invention.

FIGS. 7A to 7D are sectional views sequentially showing a process for manufacturing the electrostatic chuck member having an emboss according to the invention using the mask sheet manufactured by the method in FIGS. 6A to 6D.

FIG. 8 is a graph plotting a relationship between a roundness dimension of an edge part and the number of particles stuck to a back face of a wafer which are measured in an electrostatic chuck member having an emboss according to an example 1.

FIG. 9 is a graph plotting a change in a dechuck characteristic in the electrostatic chuck member having an emboss fabricated in each of a comparative example 1 and examples 1 to 3.

FIG. 10 is a typical view showing a reason why the dechuck characteristic is improved in the electrostatic chuck member having an emboss according to the invention.

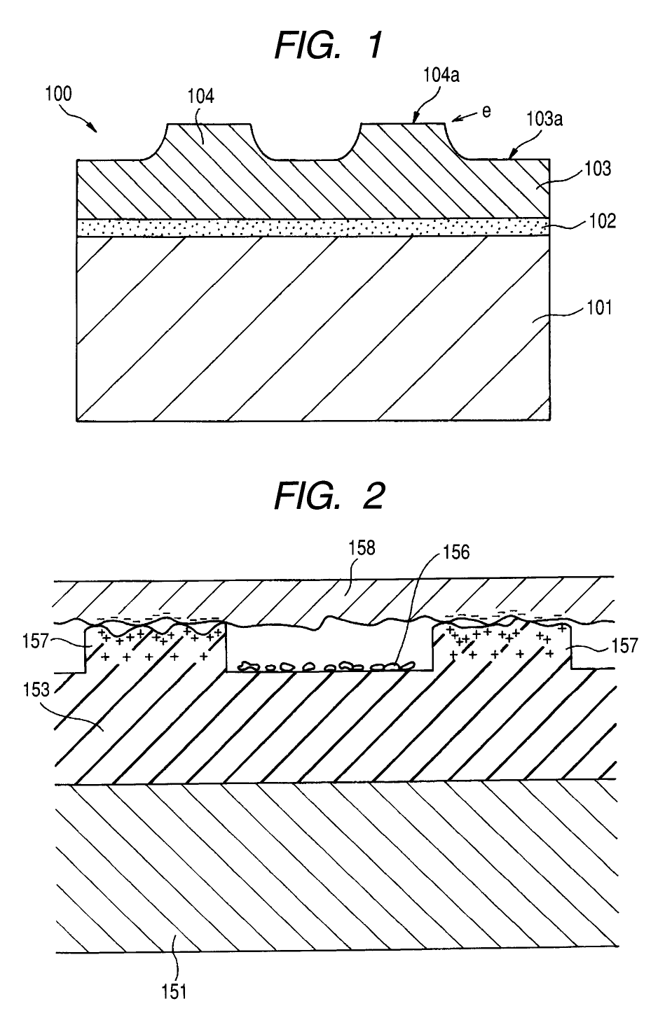

### DETAILED DESCRIPTION OF THE PREFERRED EMBODIMENTS

An electrostatic chuck member, a method of manufacturing the electrostatic chuck member, and an electrostatic chuck device according to the invention can be advantageously executed in various configurations within the scope of the invention, respectively.

The electrostatic chuck member and the electrostatic chuck device according to the invention can be advantageously used in order to catch, hold, fix and deliver various articles by utilizing an electrostatic chucking force thereof. Accordingly, their applicability is not particularly restricted. However, it is preferable that the electrostatic chuck member and the electrostatic chuck device according to the invention can be advantageously used in the manufacturing field of a semiconductor device as will be described below in detail. For example, in the manufacture of the semiconductor device, it is possible to advantageously use the electrostatic chuck member and the electrostatic chuck device when electrostatically treating various semiconductor wafers such as a silicon wafer and a gallium arsenide wafer in a chemical or physical treatment of the wafers. Examples of the treatment for the wafer can include etching, sputtering, a chemical vapor deposition process (a CVD process) and a chemical-mechanical polishing process (a CMP process) and the processes are not restricted.

The invention is characterized in that the particles (fine particles) generated particularly in the protruded portion of the electrostatic chuck device are not generated as described above. A greater part of the particles are generated between the semiconductor wafer and the protruded portion of the electrostatic chuck, and there is a possibility that the particles might be moved and laminated on a back face of the wafer during handling of the wafer, and furthermore, might be dropped onto a surface of another wafer to cause a new defect of the wafer, for example, an undesirable change in an aspect ratio of a wiring on the wafer. A composition of the particle causing the problem is therefore derived from that of the wafer or the electrostatic chuck and includes an AlOx based particle supposed to be an Al₂O₃ component and an SiOx based particle supposed to be an SiO₂ component, for example. Moreover, a size of the particle is usually equal to or smaller than approximately 0.1 to 1.0 μm. If it is possible to prevent the generation of a particle having a size which is larger than 0.2 μm, an undesirable result can be avoided.

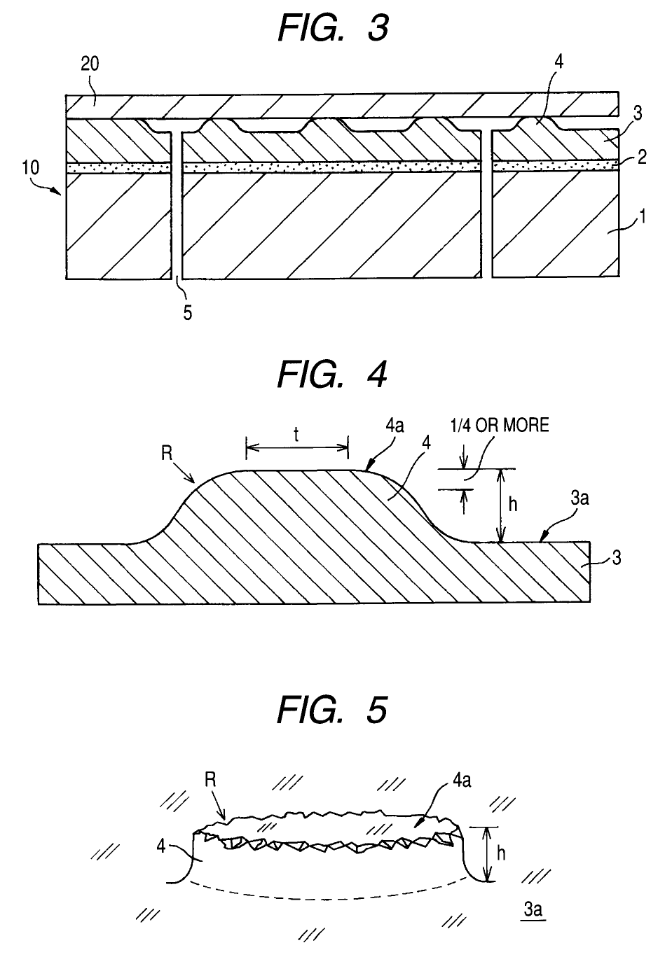

Subsequently, an electrostatic chuck device having an emboss according to the invention will be described with reference to the accompanying drawings. FIG. 3 is a sectional view showing a state in which the electrostatic chuck device according to the invention is used to electrostatically adsorb a semiconductor wafer. An electrostatic chuck device 10 usually has a disk-shaped substrate 1 having an almost equal size to a semiconductor wafer (a silicon wafer in the drawing) 20 corresponding to a shape thereof. The substrate 1 can have a thickness of approximately 20 to 40 mm and a diameter thereof can be optionally varied corresponding to a size of the semiconductor wafer 20, for example, 300 mm. The substrate 1 can be formed by a metallic material, for example, aluminum or an alloy thereof, titanium or an alloy thereof, or copper and a coat can be formed on a surface thereof through an alumite treatment or alumina spraying if necessary.

In the electrostatic chuck device 10 according to the invention, an electrostatic chuck member 3 according to the invention is integrally attached to an upper surface of the substrate 1 through an adhesive layer 2. The adhesive layer 2 can be formed in a thickness of approximately 0.01 to 0.1 mm by a silicone type or epoxy type adhesive, for example, and a brazing metal material may be used in place of the adhesive. A thickness of the electrostatic chuck member 3 is usually approximately 1 to 10 mm. Furthermore, the electrostatic chuck member 3 has a protruded portion 4 on an electrostatic chuck surface to be an upper surface thereof. The protruded portion 4 may have a shape such as a prism or a triangle pole if necessary, and preferably, is usually a cylinder. Although it is preferable that the cylinder should have a top surface taking a completely round shape, the shape may be almost completely round or elliptical if necessary. The electrostatic chuck device 10 further has a cooling gas inlet 5 having a diameter of approximately 0.1 to 1.0 mm in order to introduce a cooling gas such as a helium gas into a space interposed between the electrostatic chuck member 3 and the semiconductor wafer 20 in use and to cool the semiconductor wafer 20, for example.

In the electrostatic chuck device 10 having the structure, the semiconductor wafer 20 is adsorbed through an adsorbing electrode (not shown) so as to be stuck to the top surface of the protruded portion 4 of the electrostatic chuck member 3, and is thus held and fixed stably as shown. In particular, an excellent adsorbing effect can be achieved by an action of a mirror finished surface (Ra of 0.2 μm or less) formed in an almost central part of the top surface of the protruded portion 4. When the use of the electrostatic chuck device 10 is completed, moreover, it is possible to easily remove (dechuck) the wafer 20 from the electrostatic chuck member 3 without generating an undesirable particle between the protruded portion 4 of the electrostatic chuck member 3 and the semiconductor wafer 20. The effect is greatly obtained by a rounded portion formed on an edge part of the protruded portion 4, that is, an R portion as will be described below in detail.

With reference to FIG. 4, the protruded portion 4 of the electrostatic chuck member 3 will be described in more detail. The protruded portion 4 is formed on a surface of the electrostatic chuck member 3 through a processing thereof and the number can be optionally varied depending on a size of the electrostatic chuck member 3 (or the semiconductor wafer 20). In the case in which the semiconductor wafer 20 has a size of 12 inches, for example, approximately 100 to 500 protruded portions 4 are provided. It is preferable that each of the top surfaces of the protruded portions should have a diameter of approximately 0.2 to 2 mm and a height of approximately 0.01 to 0.03 mm. In the invention, the protruded portions 4 can be referred to as an “embossed layer”, and furthermore, an arrangement pattern of the protruded portion 4 can be optionally varied in the embossed layer. For example, the protruded portion 4 may be arranged concentrically or randomly with a center of the electrostatic chuck member 3 set to be a reference.

The electrostatic chuck member 3, that is, the base material 3 and the protruded portion 4 can be formed by optional materials and can be preferably formed by a fragile material, a metallic material, a resin material or a complex thereof. Examples of the metallic material include stainless, an aluminum alloy, a titanium alloy, and other non-ferrous metals which have surfaces subjected to alumina spraying or an alumite treatment, and examples of the fragile material can include alumina ceramic, alumina nitride, silicon carbide and quartz. Moreover, examples of the resin material can include polyimide based, nylon based and fluorine based resin materials. In consideration of use on a severe condition in the manufacture of the semiconductor device, it is possible to advantageously use the alumina ceramic and the materials subjected to the alumina spraying.

In the electrostatic chuck member 10 formed by the material, the protruded portion 4 can be formed by a mechanical grinding method, for example, a method of carrying out a processing through a machining center using a drill coated with diamond or a method of carrying out an etching processing through sand blasting. In general, the sand blasting method is suitable because of a low processing cost and a uniform processing. In the sand blasting method, for example, masking unit, for example, an elastic resin material such as an urethane resin is previously provided on an upper surface of a protruded portion to be formed or a portion which should not be subjected to the sand blasting, and the sand blasting is carried out over the masking unit which is present. For a blasting material to be used in the sand blasting, it is possible to advantageously use a grinding material having a hardness and a toughness which are equal to or more than those of an electrostatic chuck member to be a shaved material for example, a silicon carbide (SiC) based grinding material or an alumina (Al₂O₃) based grinding material. In the sand blasting method, masking unit put previously on the electrostatic chuck member serves as a protective film and a blasting material directly hits on only a portion which is not subjected to masking and the same portion is processed selectively. Accordingly, it is possible to obtain an electrostatic chuck member including a protruded portion having a desirable shape and dimension.

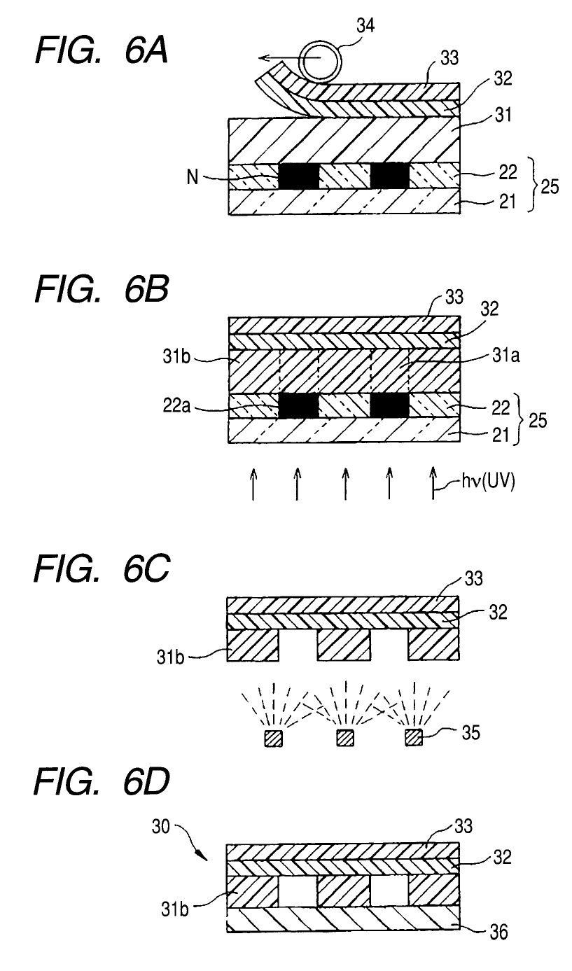

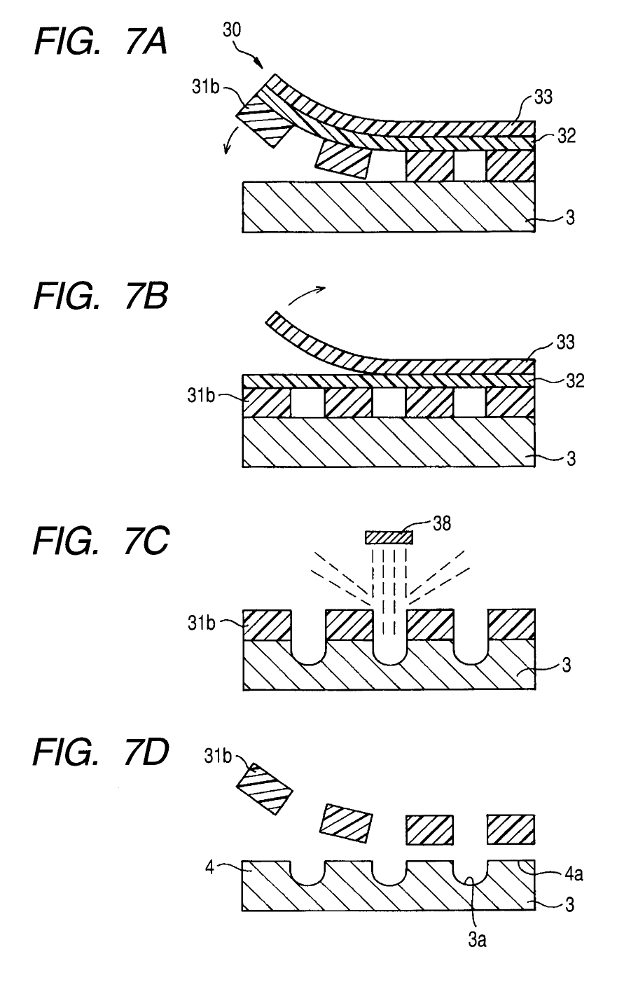

The sand blasting method will be described more specifically. It is possible to execute the sand blasting method sequentially in FIGS. 6A to 6D and FIGS. 7A to 7D. FIGS. 6A to 6D show a mask fabricating process and FIGS. 7A to 7D show a process for executing the sand blasting by using the fabricated masking unit. In the example, since the masking unit to be fabricated is sheet-shaped, it will be hereinafter referred to as a “mask sheet”.

First of all, a negative 25 to be an original form for fabricating a mask sheet is prepared as shown in FIG. 6A. The negative 25 is constituted by a glass plate 21 and a negative film 22 laminated thereon. The negative film 22 has a negative pattern N which corresponds to a non-protruded portion (a region to be etched in the sand blasting of the electrostatic chuck member). A resin sheet 31 for forming a protruded portion of the mask sheet (which can act as a protective film to prevent the etching of the electrostatic chuck member in the sand blasting) is laminated on the negative 25. The resin sheet 31 is formed by a photoresist or a similar material thereto and is exposed to ultraviolet rays and is thus subjected to a crosslinking reaction at a step in a subsequent stage, and also remains in a development so that the protruded portion of the mask sheet can be formed. Furthermore, a PET film 33 is laminated on the resin sheet 31 through a movement of a pressing roll 34 in a direction of an arrow so as to be used as a support film in the mask sheet thus obtained. In order to bond the PET film 33 to the resin sheet 31, moreover, a releasing sheet 32 which has a resistance to a developer is used at a developing step in the subsequent stage.

As shown in FIG. 6B, next, an ultraviolet exposure is carried out over the resin sheet 31. The ultraviolet exposure can be executed in accordance with a normal method on a condition specified by the resin sheet 31. As a result of the exposure, a region of the resin sheet 31 (an exposed region 31b) which is not shielded through the forward negative pattern N is subjected to a crosslinking reaction and is thus cured. A change is not observed in a non-exposed region 31a of the resin sheet 31.

After the exposing step is completed, a transition to a developing step shown in FIG. 6C is carried out. First of all, the negative 25 used in the previous exposing step is removed to expose the resin sheet 31. On the other hand, a suitable developing solution is jetted from a developing device 35 onto the resin sheet 31. Consequently, only the non-exposed region 31a which is not subjected to the exposure at the previous step is selectively washed away so that the exposed region 31b remains on the PET film 33 as shown. Since the non-exposed region 31a is washed away at the step, the step may be referred to as a “washing step” in place of the developing step. After the development, the resin sheet 31 is washed with pure water if necessary and is then dried.

As shown in FIG. 6D, finally, a releasing paper 36 is laminated on the resin sheet 31. It is possible to protect, through the releasing paper 36, a protruded portion which is formed in the exposed region 31b of the resin sheet 31 and is to be used as a protective film at a sand blasting step in a subsequent stage. In a mask sheet 30 thus obtained, the releasing paper 36 can easily be removed immediately before the use of the mask sheet 30.

Subsequently, a transition to the sand blasting step shown sequentially in FIGS. 7A to 7D is carried out. First of all, an electrostatic chuck member 3 which is to be subjected to sand blasting, for example, alumina ceramic (a thickness of 1 to 10 mm) having a purity of 90 to 98% is prepared as shown in FIG. 7A. The mask sheet 30 fabricated at the previous step is laminated with the exposed region 31b turned downward.

Since the exposed region 31b of the resin sheet 31 is adhesive, there is no worry that it is removed after adhesion.

After the mask sheet 30 is laminated on the electrostatic chuck member 3, the PET film 33 used as the support film is peeled from the mask sheet 30 as shown in FIG. 7B.

As shown in FIG. 7C, then, an ordinary blasting device 38 is used to carry out blasting. When the sand blasting is executed, the releasing sheet 32 remaining on the mask sheet is first removed with a blasting material, and furthermore, the remaining exposed region 31b serves as masking unit, and the blasting material directly hits on only a portion which is not masked and the same portion is selectively processed.

As shown in FIG. 7D, finally, the exposed region 31b used as the masking unit is peeled and removed. As a result, the electrostatic chuck member 3 including the protruded portion 4 having a desirable shape and dimension is obtained as shown. The top surface 4a of the protruded portion 4 is a mirror finished surface. Subsequently, an edge part of the protruded portion can be subjected to a smoothing treatment in accordance with the invention, which is not shown.

Referring to FIG. 4 again, the protruded portion 4 of the electrostatic chuck member 3 has a roundness (R) of approximately 0.01 mm or more applied to the edge part specified by an intersection of the top surface and a side surface. When the roundness is smaller than 0.01 mm, a sharpness is increased in the edge part. As a result, the degree of the generation of a particle is increased and a dechuck characteristic is also deteriorated. The change in the characteristic also depends on a size of the portion to which the roundness is applied. According to the knowledge of the inventor, the portion having the roundness is to occupy approximately a quarter of a height h of the protruded portion 4 or more in the protruded portion 4 of the electrostatic chuck member 3. When the same portion is smaller than the quarter, the action of the roundness is not sufficient. Accordingly, the degree of the generation of the particle is increased so that the dechuck characteristic is also deteriorated.

In the top surface of the protruded portion 4, furthermore, an almost central part (a portion shown in t in the drawing) has a mirror finished surface maintained by a protection through the masking unit. Similarly, it is possible to contribute to a prevention of the generation of the particle and an enhancement in the dechuck characteristic. In the case in which the mirror finished surface is represented by a surface roughness of Ra, it is preferable that Ra should be equal to or smaller than approximately 0.2 μm. Moreover the surface 3a excluding the protruded portion 4 of the electrostatic chuck member 3 is a surface subjected to the blasting and the surface roughness Ra is usually approximately 0.2 to 1.0 μm. In the case in which additional blasting is carried out to apply the roundness, it is possible to further reduce the surface roughness Ra to be 0.3 μm or less, for example.

In the embodiment, the application of the roundness to the protruded portion of the electrostatic chuck member 3 can be achieved by various techniques. For example, it is preferable that the application can be achieved by:

forming a protruded portion on the electrostatic chuck surface through embossing and then smoothing an edge part of the protruded portion through a post-processing including polishing or blasting, or

smoothing the edge part of the protruded portion when forming the protruded portion on the electrostatic chuck surface through the embossing.

The work for smoothing the edge part of the protruded portion will further be described. The method can be advantageously executed by the following technique, for example.

(1) The protruded portion is formed on the electrostatic chuck surface through the embossing and the edge part of the protruded portion is then processed by a softer grinding material than the electrostatic chuck member under the presence of masking unit for protecting at least the central part of the top surface of the protruded portion, thereby applying the roundness to the protruded portion. In case of the method, the use of the masking unit may be omitted if necessary.

(2) The protruded portion is formed on the electrostatic chuck surface through the embossing and the edge part of the protruded portion is then processed by a grinding material having finer abrasive grains than the grinding material used in the embossing, thereby applying the roundness to the protruded portion. In case of the method, the masking unit for protecting at least the central part of the top surface of the protruded portion may be used if necessary.

(3) When the protruded portion is to be formed on the electrostatic chuck surface through the embossing, the protruded portion is processed by a grinding material having a grain size of 250 to 44 μm in a state in which the edge part is exposed under the presence of negative type masking unit corresponding to the top surface of the protruded portion to be formed, thereby applying the roundness to the protruded portion.

Further specific description will be given to the respective techniques. The first smoothing method (1) serves to smooth, through the post-processing, the protruded portion formed on the surface of the electrostatic chuck member through the embossing. In the method, the protruded portion can be formed through the embossing by the method described above with reference to FIGS. 6A to 6D and FIGS. 7A to 7D. Then, proper masking unit is superposed on the surface of the electrostatic chuck member in order to protect the mirror finished surface formed on the top surface of the protruded portion, particularly, to protect at least the central part of the top surface of the protruded portion and a vicinal portion thereof. The electrostatic chuck member is covered with the masking unit. Therefore, the formed edge part is exposed. In this state, the edge part of the protruded portion is processed by means of the softer grinding material than the electrostatic chuck member under the presence of the masking unit. An optional member can be used as the masking unit and the masking unit having an elasticity may be employed, for example. Preferably, the edge part can be processed by wrapping using a free abrasive grain. For a processing machine, it is possible to use a wrapping machine or a polishing machine, for example. Moreover, the abrasive grain which can be used includes an alumina based abrasive grain, a silicon carbide based abrasive grain, and a diamond abrasive grain, and a grain size of the abrasive grain is usually approximately size of 14 to 4 μm. The wrapping can be executed by using a proper processing machine. However, it is desirable to carry out the processing as softly as possible. For this reason, it is also preferable to execute the processing by a manual work in place of a mechanical processing. For example, it is possible to polish the whole surface of the electrostatic chuck member by hands in a wet condition by using an abrasive paper having an abrasive grain surface without using the masking unit together. In addition, it is also possible to employ a brush mixing an abrasive grain therein and a method of polishing the free abrasive grain by means of a nylon brush.

By carrying out the wrapping as described above, it is possible to apply the roundness to the protruded portion 4 of the electrostatic chuck member 3 as typically shown in FIG. 4. In the round portion which is formed, the wrapping is carried out through free abrasive grains or hand polishing so that the edge part is processed mainly to have a roundness of R=0.01 mm or more. Moreover, the round portion has a size which is equal to or larger than a quarter of the height h of the protruded portion 4. For example, when the height h of the protruded portion 4 is 0.03 mm, the round portion has a size of approximately 0.01 mm. Since a region of the central part t of the top surface 4a is protected by the masking unit in the wrapping, moreover, it is maintained to be mirror finished and has a surface roughness of Ra=0.2 μm or less. It is possible to achieve the surface roughness by properly selecting an abrasive grain and a grain size for the previous blasting so as not to change the roughness of the top surface. Referring to the method, furthermore, it is also possible to grind the side surface of the protruded portion 4 and the non-protruded portion (bottom face) 3a of the electrostatic chuck member 3. Therefore, the roughness in each of the portions can further be reduced. For example, the surface roughness Ra of the bottom face 3a of the electrostatic chuck member 3 can be reduced to be approximately 0.3 μm. Referring to the method, particularly, the abrasive grains also go around the bottom face 3a of the electrostatic chuck member 3. Therefore, the bottom face 3a roughened by the blasting is also close to a mirror surface. Thus, it is possible to suppress the generation of the particle more effectively.

The second smoothing method (2) also serves to smooth, through a post-processing, the protruded portion formed on the surface of the electrostatic chuck member by the embossing. The method uses the smoothing through the blasting in place of the wrapping through the free abrasive grain used in the first smoothing method. Referring to the method, the method described above with reference to FIGS. 6A to 6D and FIGS. 7A to 7D can be executed until the protruded portion is formed through the embossing. Then, the edge part of the protruded portion is processed by means of a grinding material having finer abrasive grains than the grinding material used in the embossing under non-presence of the masking unit so that a roundness is applied to the protruded portion. In the blasting for the edge part, a sand blasting machine can be used as a processing machine, for example. Moreover, the abrasive grains which can be used include an alumina based abrasive grain, a silicon carbide based abrasive grain, a boron nitride based abrasive grain and a diamond abrasive grain. The abrasive grain usually has a grain size of approximately 14 to 4 μm. In case of the method, it is also possible to use masking unit for protecting at least the central part of the top surface of the protruded portion if necessary.

By carrying out the blasting as described above, it is possible to apply the roundness to the protruded portion 4 of the electrostatic chuck member 3 as typically shown in FIG. 4, for example. In the round portion which is formed, the edge part is comparatively fragile. Therefore, a roundness of R=0.01 mm or more is applied through the blasting. Moreover, the round portion has a size which is equal to or larger than a quarter of the height h of the protruded portion 4. For example, when the height h of the protruded portion 4 is 0.03 mm, for example, the size of the round portion is approximately 0.01 mm. Since the region of the central part t of the top surface 4a is not positively subjected to the blasting, moreover, it is maintained to be mirror finished and the surface roughness of Ra=0.2 μm or less is obtained. It is possible to achieve the surface roughness by properly selecting the abrasive grain and the grain size for the previous blasting so as not to change the roughness of the top surface. According to the method, furthermore, the side surface of the protruded portion 4 and the non-protruded portion (bottom face) 3a of the electrostatic chuck member 3 can also be subjected to the blasting. Therefore, the roughness in each of the portions can further be reduced. For example, the surface roughness Ra of the bottom face 3a of the electrostatic chuck member 3 can be reduced to be approximately 0.3 μm. According to the method, particularly, the blasting is utilized. Therefore, there is an advantage in that the processing can easily be carried out and the rough bottom face 3a of the electrostatic chuck member 3 is slightly smoothed.

The third smoothing method (3) serves to carry out smoothing to break the edge part, that is, to smooth the protruded portion by utilizing a plastic fracture of the edge part in the embossing when forming the protruded portion on the surface of the electrostatic chuck member through the embossing. In case of the method, it is possible to process the protruded portion by means of a rough grinding material with the edge part exposed by using the negative type masking unit corresponding to the top surface of the protruded portion to be formed on the surface of the electrostatic chuck member through the embossing, thereby applying a desirable roundness to the protruded portion when forming the protruded portion.

The method of forming the protruded portion through the embossing can be basically executed by the method described with reference to FIGS. 6A to 6D and FIGS. 7A to 7D. Moreover, the masking unit to be used in that case may be the means described above or the other masking unit. If necessary, the use of the masking unit may be omitted. The embossing can be preferably executed by the blasting and can be further preferably executed by the sand blasting. In the blasting for the edge part, a sand blasting machine can be used for a processing machine, for example. The abrasive grain which can be used includes a silicon carbide based abrasive grain and a diamond abrasive grain. It is preferable that the abrasive grain should have a grain size of 250 to 44 μm.

By carrying out the blasting as described above, it is possible to apply the roundness to the protruded portion 4 of the electrostatic chuck member 3 as typically shown in FIG. 5, for example. In the round portion which is formed, the edge part is comparatively fragile. Therefore, a roundness of R=0.01 mm or more is applied through the blasting. Moreover, the round portion has a size which is equal to or larger than a quarter of the height h of the protruded portion 4. For example, when the height h of the protruded portion 4 is 0.03 mm, the round portion has a size of approximately 0.01 mm. Referring to the round portion in the method, the embossed surface is greatly damaged by the rough grinding material so that a sharp edge is broken. For this reason, an external appearance shown typically in FIG. 5 is obtained. The external appearance also prevents the generation of the particle effectively. Since the region of the central part t of the top surface 4a is protected by the masking unit in the blasting, moreover, it is maintained to be mirror finished and the surface roughness of Ra=0.2 μm or less is obtained. It is possible to achieve the surface roughness by properly selecting the abrasive grain and the grain size for the previous blasting so as not to change the roughness of the top surface. According to the method, particularly, it is possible to form the protruded portion through the blasting and to smooth the edge part of the protruded portion through one step at the same time. Therefore, there is an advantage in that the manufacturing process can be shortened and the productivity can be enhanced.

### EXAMPLE

Subsequently, the invention will be described with reference to examples thereof. It is apparent that the invention is not restricted to the examples.

### Comparative Example 1

In the example, a protruded portion is formed on a surface of an electrostatic chuck member through embossing to fabricate an electrostatic chuck member having a protruded portion. In the example, for comparison, a post-treatment for smoothing is not carried out over an edge part of the protruded portion of the electrostatic chuck member thus fabricated.

With reference to FIGS. 6A to 6D, a mask sheet is fabricated in accordance with the technique described above. The mask sheet is a positive type acrylic resin film in a thickness of 70 μm which includes, as a support film, a PET film in a thickness of 80 μm. The resin film is formed in a positive pattern corresponding to the protruded portion of the electrostatic chuck member.

In accordance with the technique described above with reference to FIGS. 7A to 7D, next, the electrostatic chuck member having a protruded portion is fabricated. The electrostatic chuck member prepared in the example is laminated on a substrate formed of aluminum having a diameter of 300 mm and a thickness of 30 mm through a silicone based adhesive having a thickness of 0.1 mm and is constituted by 96% alumina ceramic having a diameter of 300 mm and a thickness of 1 mm. Subsequently, the mask sheet fabricated at the previous step is laminated on the electrostatic chuck member with the positive pattern turned downward. After the PET film is peeled from the mask sheet, blasting is carried out by using an ordinary sand blasting machine. In the example, a silicon carbide based abrasive grain is used as a blasting material and has a grain size of an average particle size of 30 μm. As a result of the sand blasting, the positive pattern of the mask sheet is used as a mask so that the electrostatic chuck member exposed from the substrate is removed to have a predetermined depth through etching. More specifically, a blasting material directly hit on only a portion of a surface of the electrostatic chuck member which is not masked and the same portion is processed selectively. The etching is stopped when the depth corresponds to the height of the protruded portion. When the positive pattern used as the masking unit is finally peeled and removed, an electrostatic chuck member including a protruded portion having a sharp edge part is obtained. The protruded portions are arranged concentrically from a center of the electrostatic chuck member and the number thereof is 360. Moreover, a dimension of the protruded portion had a diameter of 1 mm and a height of 0.01 mm.

### Example 1

In the example, an electrostatic chuck member having a protruded portion is fabricated by a method of smoothing, through wrapping using a free abrasive grain, an edge part of the protruded portion formed on a surface of the electrostatic chuck member through embossing.

There is prepared the electrostatic chuck member formed of alumina ceramic which is fabricated in the comparative example 1. The electrostatic chuck member had a diameter of 300 mm and a thickness of 1 mm and included 360 protruded portions having a diameter of 1 mm and a height of 0.01 mm in total.

Subsequently, the surface of the electrostatic chuck member is subjected to the wrapping using a free abrasive grain. In the example, a wrapping machine put on the market is used and an edge part of the protruded portion is processed by a softer grinding material than the electrostatic chuck member. The grinding material used herein is an alumina based abrasive grain. In order to vary a size (mm) of a roundness of the edge part within a range of 0, 0.05, 0.01, 0.02 and 0.05, an abrasive grain having a grain size of 4 μm is selected to change a wrapping time so that a roundness having a predetermined size is obtained.

By carrying out the wrapping as described above, there is obtained an electrostatic chuck member including a protruded portion having different roundnesses in respective edge parts as shown in the following Table 1. Any of the formed round portions to which a roundness is applied had a size which is equal to or larger than a quarter of a height of the protruded portion. A central part of a top surface of the protruded portion maintained a mirror surface also after the wrapping. Although the edge parts had the different roundnesses, it is found that the number of generated particles can be reduced to be approximately a half or more as compared with R=0 mm in an edge part having a roundness of R=0.01 mm or more as a result of a subsequent evaluation test, which is very effective.

### Example 2

In the example, an electrostatic chuck member having a protruded portion is fabricated by a method of smoothing, through blasting, an edge part of the protruded portion formed on a surface of the electrostatic chuck member through embossing.

There is prepared the electrostatic chuck member formed of alumina ceramic which is fabricated in the comparative example 1. The electrostatic chuck member had a diameter of 300 mm and a thickness of 1 mm and included 360 protruded portions having a diameter of 1 mm and a height of 0.01 mm in total.

In order to cause a mirror surface formed on a surface of the protruded portion to protect a surface to be processed, subsequently, a mask having a diameter of 0.5 mm which is smaller than an embossing diameter is laminated on an embossed surface. The mask used in the example is a mask sheet formed by the same material as that used in the formation of the protruded portion in the comparative example 1. An edge part of the protruded portion is subjected to blasting with a grinding material having finer abrasive grains than the grinding material used in the embossing in the comparative example 1. In the blasting for the edge part, a sand blasting machine is used as a processing machine and the abrasive grain is an alumina based abrasive grain having a grain size of an average particle size of 14 to 4 μm. In order to obtain a roundness of 0.05 mm in the edge part, the grain size of the abrasive grain is selected properly.

By carrying out the blasting as described above, there is obtained an electrostatic chuck member including a protruded portion having a roundness of R=0.05 mm in an edge part. Any of the formed round portions to which the roundness is applied had a size which is equal to or larger than a quarter of a height of the protruded portion. Since a central part of a top surface of the protruded portion is protected by the mask in the blasting, it had a mirror finished surface having a surface roughness of Ra=0.2 μm or less.

### Example 3

In the example, an electrostatic chuck member having a protruded portion is fabricated by a method of smoothing the protruded portion through embossing so as to break an edge part in the embossing when forming the protruded portion on a surface of the electrostatic chuck member through the embossing.

There is prepared the mask sheet fabricated in the comparative example 1. The mask sheet is a positive type acrylic resin film in a thickness of 50 μm which includes, as a support film, a PET film in a thickness of 80 μm. The resin film is formed in a positive pattern corresponding to the protruded portion of the electrostatic chuck member.

According to the technique described above with reference to FIGS. 7A to 7D, next, the electrostatic chuck member having a protruded portion is fabricated in accordance with the invention. The electrostatic chuck member prepared in the example is laminated on a substrate formed of aluminum having a diameter of 300 mm and a thickness of 30 mm through a silicone based adhesive having a thickness of 0.1 mm and is constituted by 96% alumina ceramic having a diameter of 300 mm and a thickness of 1 mm. Subsequently, the mask sheet fabricated at the previous step is laminated on the electrostatic chuck member with the positive pattern turned downward. After the PET film is peeled from the mask sheet, blasting is carried out by using an ordinary sandblasting machine. In the example, a silicon carbide based abrasive grain is used as a blasting material and had a grain size of an average particle size of 250 to 44 μm. In order to obtain a roundness of 0.05 mm in an edge part, a grain size of an abrasive grain is selected properly.

As a result of the sand blasting, the positive pattern of the mask sheet is used as a mask so that the electrostatic chuck member exposed from the substrate is removed to have a predetermined depth through etching. More specifically, a blasting material directly hit on only a portion of a surface of the electrostatic chuck member which is not masked and the same portion is processed selectively. The etching is stopped when the depth corresponds to the height of the protruded portion. When the positive pattern used as the mask is finally peeled and removed, the edge part is broken due to a plastic fracture so that an electrostatic chuck member including a protruded portion having a roundness of R=0.05 mm is obtained. Any of the formed round portions to which the roundness is applied had a size which is equal to or larger than a quarter of a height of the protruded portion. Since a central part of a top surface of the protruded portion is protected by the mask in the blasting, it had a mirror finished surface having a surface roughness of Ra=0.2 μm or less.

### Test Example 1

### (1) Evaluation of Generation of Particle

In the example, a characteristic of the electrostatic chuck member having a protruded portion which is fabricated in each of the comparative example 1 and the examples 1 to 3 is evaluated based on the number of particles generated due to a friction of the semiconductor wafer (the silicon wafer) and the electrostatic chuck member and stuck to a back face of the silicon wafer. For the evaluation test, a wafer surface inspecting device is used.

The electrostatic chuck member according to each of the examples is attached to an electrostatic chuck having a bipolar heater (formed of 96% alumina ceramic). A silicon wafer having a thickness of 0.8 mm and a size of 12 inches which includes an SiO₂ film (a thickness of 100 nm) on both sides is adsorbed and fixed into the electrostatic chuck member. The wafer is adsorbed and fixed through an application of a voltage of 300 V to electrodes for three minutes at 100°. Then, the applied voltage is turned OFF. The silicon wafer is removed from the electrostatic chuck to measure, through a particle counter, the number of the particles (>0.2 μm) stuck to the back face of the silicon wafer after the removal. A result of the measurement described in the following Table 1 is obtained.

TABLE 1

| | Comparative | | | |
|---|---|---|---|---|
| | Example 1 | Example 1 | Example 2 | Example 3 |
| Number of | 360 | 360 | 360 | 360 |
| Embosses | | | | |
| Dimension | Diameter 1 mm × | Diameter 1 mm × | Diameter 1 mm × | Diameter 1 mm × |
| of Emboss | Height 0.01 mm | Height | Height | Height |
| | | 0.01 mm | 0.01 mm | 0.01 mm |
| Number of | 0.07/mm² | 0.01/mm² | 0.03/mm² | 0.05/mm² |
| Particles | | | | |
| (>0.2 μm) | | | | |

As shown in the Table 1, in the case in which the edge part is smoothed in accordance with the invention, it is possible to remarkably suppress the generation of the particles which might be stuck to the back face of the wafer in contrast to the case in which the electrostatic chuck member having the sharp edge part is exactly used as in the comparative example 1. Accordingly, it is possible to prevent a deterioration in the characteristic of the wafer from being caused by a drop of the particles.

(2) Consideration of Relationship between Roundness Dimension of Edge Part and Number of Generated Particles

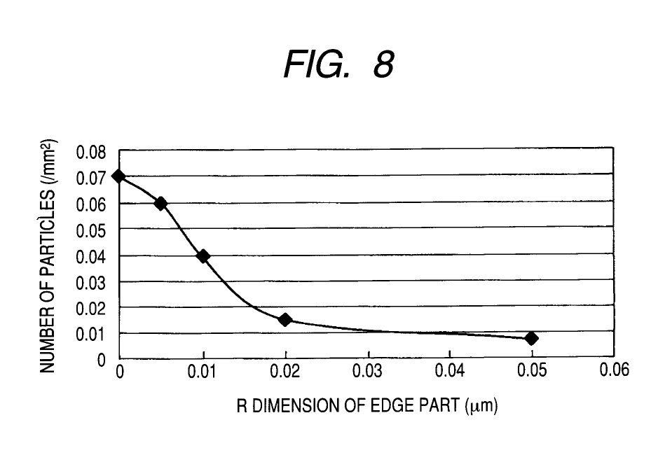

For the electrostatic chuck member having different roundness dimensions in the edge parts which is fabricated in the example 1, a relationship between the roundness dimension of the edge part and the number of the particles stuck to the back face of the wafer is checked so that a graph plotted in FIG. 8 is obtained. As is understood from the graph, by regulating the roundness dimension of the edge part to be 0.01 mm or more, it is also possible to reduce the number of the generated particles to be an almost half or less.

### Test Example 2

### Evaluation of Dechuck Characteristic

In the example, there is evaluated a dechuck characteristic obtained when the semiconductor wafer (the silicon wafer) is taken out of the electrostatic chuck member having a protruded portion which is fabricated in each of the comparative example 1 and the examples 1 to 3. In the evaluation test, a transverse pushing proof stress of the silicon wafer is measured by using a digital force gauge.

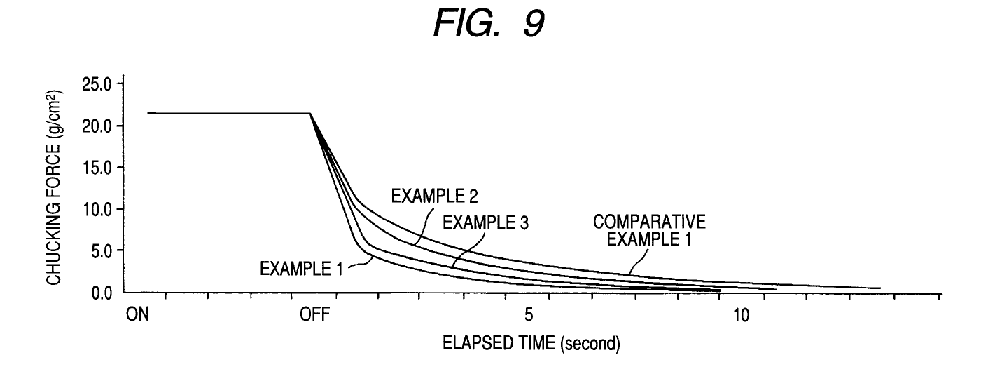

The electrostatic chuck member according to each of the examples is attached to an electrostatic chuck having a bipolar heater (formed of 96% alumina ceramic). A silicon wafer having a thickness of 0.8 mm and a size of 12 inches which includes an SiO₂ film (a thickness of 100 nm) on both sides is adsorbed and fixed into the electrostatic chuck member. The wafer is adsorbed and fixed through an application of a voltage of 300 V to electrodes for three minutes at 100°. Then, the applied voltage is turned OFF. The silicon wafer is pushed against the electrostatic chuck member in a horizontal direction through the digital force gauge and a change in the proof stress in that case is measured with the passage of time. In the example, the proof stress thus obtained is regarded as a chucking force (unit 9/cm²). As a result of the measurement, there is obtained a graph indicative of a change in the dechuck characteristic in the electrostatic chuck member as is plotted in FIG. 9.

As will be understood from the result of the measurement shown in FIG. 9, in the case in which the edge part is smoothed in accordance with the invention, it is possible to achieve an improvement in the dechuck characteristic proved by a rapid reduction in the chucking force rapidly immediately after the start of lift-up of the wafer from the electrostatic chuck member in contrast to the case in which the electrostatic chuck member having the sharp edge part is used as in the comparative example 1.

According to the consideration of the inventor, it is possible to suppose that a remarkable improvement in the dechuck characteristic which can be achieved by the invention greatly depends on the fact that:

air can quickly enter the edge part when the air opening is carried out in a vacuum state of adsorption; and

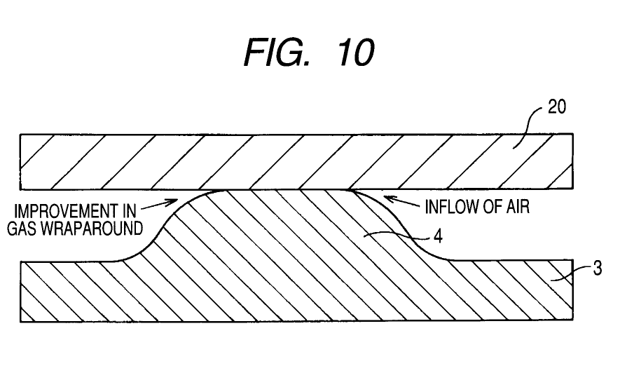

a cooling gas wraparound can be enhanced because the edge part is rounded in the edge part having the roundness in the protruded portion 4 formed on the electrostatic chuck member 3 when the silicon wafer 20 is separated from the electrostatic chuck member 3 as shown in FIG. 10.

According to a further consideration, in the invention, the top surface of the protruded portion formed on the electrostatic chuck member is changed from a plane to a dummy spherical surface over the central part thereof to the edge part. As a result, a contact area of the protruded portion and the wafer is reduced so that their contact is smoothed. Consequently, it is possible to first suppress the generation of the particle. In addition, the dummy spherical surface is constituted in the protruded portion so that it is possible to obtain the following advantages:

an improvement in a dechuck characteristic by a decrease in the contact area and a reduction in a tension of a spherical shape;

a promotion of a dechuck operation through a quick inflow of air into a round edge part; and

an improvement in a wafer cooling efficiency through an improvement in a gas wraparound (an improvement in a temperature distribution).

What is claimed is:

1. An electrostatic chuck member to be used for holding a substance to be processed in a manufacture of a semiconductor device, comprising:
a base material, and
a plurality of protruded portions formed on an electrostatic chuck surface of the base material through embossing, wherein
the protruded portion is distributed and arranged regularly or irregularly on the electrostatic chuck surface and has a circular or almost circular top surface shape,
a roundness (R) of 0.01 mm or more is applied to an edge part defined by an intersection of the top surface and a side surface, and
a portion to which the roundness is applied occupies a quarter of a height (h) of the protruded portion or more, and
the roundness is applied by smoothing the edge part of the protruded portion through a post-processing including polishing or blasting after forming the protruded portion on the electrostatic chuck surface through the embossing, or is applied by smoothing the edge part of the protruded portion when forming the protruded portion on the electrostatic chuck surface through the embossing.

2. The electrostatic chuck member according to claim 1, wherein
the top surface of the protruded portion has a diameter of 0.2 to 2 mm and a height of 0.01 to 0.03 mm.

3. The electrostatic chuck member according to claim 1, wherein
the base material is formed of a metal or ceramic.

4. The electrostatic chuck member according to claim 1, wherein
the base material is formed of alumina ceramic.

5. A method of manufacturing the electrostatic chuck member according to claim 1, comprising the steps of:
smoothing an edge part of the protruded portion under presence of masking unit, and
applying a roundness (R) to the edge part, wherein
the roundness is applied to the edge part of the protruded portion through a post-processing including polishing or blasting after forming the protruded portion on the electrostatic chuck surface through embossing, or is applied to the edge part of the protruded portion when forming the protruded portion on the electrostatic chuck surface through the embossing.

6. The manufacturing method according to claim 5, wherein
after forming the protruded portion on the electrostatic chuck surface through the embossing,
the edge part of the protruded portion is processed with a softer grinding material than the electrostatic chuck member under presence or non-presence of the masking unit for protecting at least a central part of a top surface of the protruded portion to apply the roundness.

7. The manufacturing method according to claim 5, wherein
after forming the protruded portion on the electrostatic chuck surface through the embossing, the edge part of the protruded portion is processed with a grinding material constituted by finer abrasive grains than a grinding material used in the embossing under presence or non-presence of the masking unit for protecting at least a central part of a top surface of the protruded portion to apply the roundness.

8. The manufacturing method according to claim 5, wherein
when forming the protruded portion on the electrostatic chuck surface through the embossing, the protruded portion is processed with a grinding material having a grain size of 250 to 44 μm in a state in which the edge part is exposed under presence of negative type masking unit corresponding to a top surface of the protruded portion to be formed to apply the roundness.

9. The manufacturing method according to claim 5, wherein
the embossing is carried out through sand blasting.

10. An electrostatic chuck device comprising:
the electrostatic chuck member described in claim 1, and
a substrate including the electrostatic chuck member with an electrostatic chuck surface exposed from an upper surface.
